(19) United States
(12) Patent Application Publication
(10) Pub. No.: US 2019/0037681 A1
(43) Pub. Date: Jan. 31, 2019

(54) HOT SWAPPABLE DEVICES

(71) Applicant: Aruba Networks, Inc., Sunnyvale, CA (US)

(72) Inventors: Vigneshwara Upadhyaya, Bangalore (IN); Arunachalaprabhu Gunasekaran, Bangalore (IN); Mukundan Gangadurai, Bangalore (IN); Hemanth Maddhula, Bangalore (IN)

(21) Appl. No.: 15/665,278

(22) Filed: Jul. 31, 2017

(51) Int. Cl. H05K 1/02

(52) U.S. Cl. CPC H05K 1/021; H05K 2201/06

(57) ABSTRACT

Example implementations relate to hot swappable devices. In an example, the system may include a hot swappable fan module and a heat source device. The heat source device may include a control circuit to control a voltage ramp rate of the control circuit when the hot swappable fan module is coupled to the heat source device.

### BACKGROUND

Electronic devices may include a circuit board such as a printed circuit board (PCB). Electrical components of the electronic device may be coupled to the PCB. The electrical components can be electrically and mechanically coupled to the circuit board and provide various functions of the electronic device.

### BRIEF DESCRIPTION OF THE DRAWINGS

FIG. 1 illustrates an example of a system to control a voltage ramp rate in accordance with the disclosure.

FIG. 2 illustrates an example of a circuit board including a control circuit to control a voltage ramp rate in accordance with the disclosure.

FIG. 3 illustrates an example of a control circuit to control a voltage ramp rate in accordance with the disclosure.

FIG. 4 illustrates an example of a system to control a voltage ramp rate in accordance with the disclosure.

### DETAILED DESCRIPTION

An electronic device may, during an operation, generate heat, which may increase an environmental temperature of the electronic device. Increased temperature may cause an abnormal operation of and/or damage the electronic device, which may further result in reduced reliability and increased replacement cost. As such, the electronic device may utilize various ways to maintain the environmental temperature of the electronic device during the operation. For example, the electronic device may be coupled to a fan that dissipates the heat generated from the electronic device.

The fan may be removably coupled to the electronic device. In some examples, the fan may be hot swappable such that the fan may be coupled to and/or decoupled from the electronic device while the electronic device is in operation. A hot swappable fan module may, in some examples, include a circuit board and various circuits to allow the hot swappable fan module to hot swap to the electronic device. However, such structural complexity (e.g., due to including the circuit board and various circuits) may reduce reliability and/or increase cost of the hot swappable fan module.

Accordingly, example implementations relate to hot swappable devices. As detailed herein, an example electrical/mechanical structure of a hot swappable fan module (e.g., hot swappable fan) in accordance with the disclosure may be simplified; and hence, may reduce cost and increase reliability of the hot swappable fan module. In various examples, a system can include the hot swappable fan module and a heat source device. The heat source device may include a control circuit to control a voltage ramp rate of the control circuit when the hot swappable fan module is coupled to the heat source device. As used herein, a voltage ramp rate refers to a particular rate at which a voltage ramps. As used herein, ramp refers to an example change. For example, voltage ramping at a particular rate can refer to a voltage linearly increasing at the particular rate, among other possibilities.

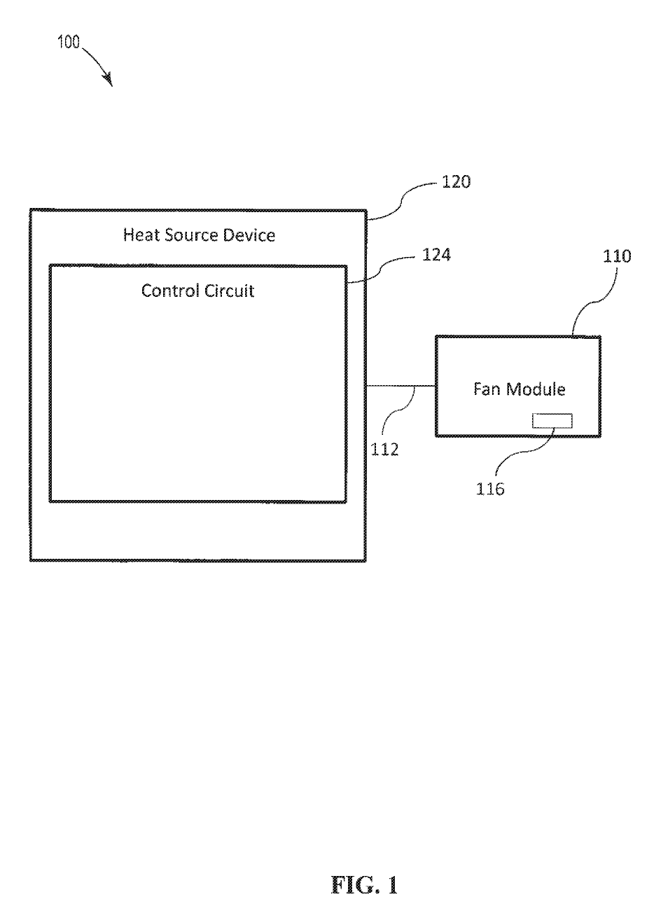

FIG. 1 illustrates an example of a system 100 to control a voltage ramp rate in accordance with the disclosure. As shown in FIG. 1, the system 100 may include a hot swappable fan module 110 and a heat source device 120. The hot swappable fan module 110 may be coupled to the heat source device 120, and the heat source device 120 may utilize the hot swappable fan module 110 to dissipate heat generated from the heat source device 120.

In various examples, the hot swappable fan module 110 may be hot swappable. That is, the module 110 may be coupled to and/or decoupled from the heat source device 120 while the heat source device 120 is in operation. The hot swappable fan module 110, when coupled to the heat source device 120, may be supplied current from the heat source device 120 to charge up uncharged capacitors of the hot swappable fan module 110.

In various examples, the hot swappable fan module 110 includes a single connector and a fan blade device. Stated differently, the hot swappable fan module 110 is free of a signal-generating electronic such as a control circuit, which controls a voltage ramp rate when the hot swappable fan module 110 is coupled to the heat source device 120. As such, a cost associated with the hot swappable fan module 110 and/or electrical interference is reduced due to the design of the hot swappable fan module 110.

In various examples, the heat source device 120 may include the control circuit 124. The heat source device 120 may utilize the control circuit 124 to control a voltage ramp rate of the control circuit when the hot swappable fan module 110 is coupled to the heat source device. That is, in the system 100, the heat source device 120 is the one that controls an output voltage of the control circuit 124 to ramp at a particular rate when the hot swappable fan module 110 is coupled to the heat source device 120.

In various examples, the heat source device 120 may include a circuit board, on which the control circuit 124 may be implemented. As such, in some examples, the hot swappable fan module 110 may be coupled to the circuit board to receive a signal generated from the control circuit 124.

In various examples, the circuit board can be a PCB or a printed circuit board assembly (PCBA), among other possibilities. As used herein, a PCB refers to circuit board suitable to electrically connect and mechanically support various electrical components. Examples of PCBs include single sided PCB, double sided PCB, and/or multi-layered PCBs, among other types of PCBs. As used herein, a PCBA refers to PCB that has undergo post processing such as printing of solder paste on the PCB and/or undergone mounting of various electrical components such as capacitors, resistors, integrated circuits, among other types of electrical components.

In some examples, the circuit board can include a power source such as source of direct current (DC) and/or a source of alternating current (AC). Examples of power sources include batteries, AC/DC power converters, and/or DC/AC power converters, among other types of power sources.

Controlling the voltage ramp rate during the hot swapping (e.g., hot swappable fan module 110 being coupled to the heat source device 120) enables a safe hot swapping and reduces risk of damaging the system 100. For example, a system may lack a capability to control the voltage ramp rate when a hot swappable fan module 110 is coupled to a heat source device 120. In this example, uncharged capacitors of the hot swappable fan module 110 may demand as much current as is available to charge over a substantially short period of time. As used herein, the term “substantially” can, for example, intend that the characteristic is not absolute, but is close enough so as to achieve the advantages of the characteristic. As such, hot swapping without limiting the demand may cause an electrical and/or physical damage to the heat source device 120 and/or the hot swappable fan module 110 due to, for example, an excessive amount of current that the system 100 is not capable of handling for the substantially short period of time. Therefore, by controlling the voltage ramp rate, the control circuit 124 supplies an amount of current to the hot swappable fan module 110 in a non-rushing manner.

In various examples, the control circuit 124 may detect current changes when the hot swappable fan module 110 is coupled to the heat source device 120 to indicate that a load (e.g., of the hot swappable fan module 110) is applied. In some examples, the control circuit 124 may reset an output voltage of the control circuit 124 when the current changes corresponding to the coupling of the hot swappable fan module 110 is detected.

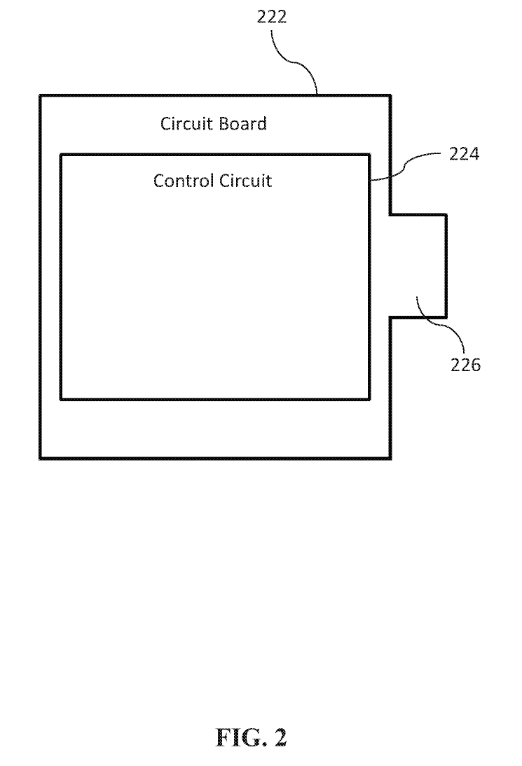

FIG. 2 illustrates an example of a circuit board 222 including a control circuit 224 to control a voltage ramp rate in accordance with the disclosure. As described herein, the circuit board 222 may be a printed circuit board (PCB).

In various examples, the PCB 222 may include a protrusion 226 formed on an edge of the PCB. As used herein, an edge may refer to an outside limit of a body. For example, an edge of the PCB may refer to an outside limit of a square-shaped PCB body (e.g., square-shaped body 222 excluding the protrusion 226).

The protrusion 226 may be utilized to couple the circuit board 222. For example, a hot swappable fan module (e.g., hot swappable fan module 110) may include a connector that mates with the protrusion 226 to receive signals generated from the PCB 222. Although one protrusion is illustrated in FIG. 2, a total number, shape, and/or relative orientation of the protrusions can be varied. For example, a total number of the protrusion 226 can be varied to include more protrusions. In some examples, the PCB 222 may include more than one protrusion 226 such that more than one hot swappable fan modules can be coupled to the signal PCB 222.

In various examples, the protrusion 226 may be a signal connector. For example, a signal circuit may be formed on the protrusion to carry signals generated from the control circuit 224 to the hot swappable fan module. As such, the hot swappable fan module coupled to the PCB 220 may operate responsive to signals generated and received from the control circuit 224 via the protrusion 226.

In various examples, controlling the voltage ramp rate is dependent on the signals generated and received from the control circuit 224 via the protrusion 226. As such, when the hot swappable fan module is coupled to (e.g., hot swapped to) the PCB 222, the control circuit 224 of the PCB 220 may generate a signal to limit the voltage ramp rate and transmit the signal to the hot swappable fan module via the protrusion 226 while the hot swappable fan module lacks an ability to control the voltage ramp rate. As such, the hot swappable fan module may include one fan blade device and one connector, which is coupled to the protrusion 222 and is utilized to receive the signal from the protrusion 222.

As shown in FIG. 2, the protrusion 226 and the PCB 222 comprise a single body. For example, the protrusion 226 may be an indistinguishable portion of the PCB 222 such that, when the hot swappable fan module is coupled via the protrusion 226, the hot swappable fan module is in direct contact with the PCB 222. As used herein, a “portion” refers to a piece of a segment of an object such as a protrusion. Coupling the hot swappable fan module directly to the PCB 222 may provide benefits such as increased transmission speed (e.g., transmission of signals generated at the control circuit 224) and increased transmission reliability, among other possibilities.

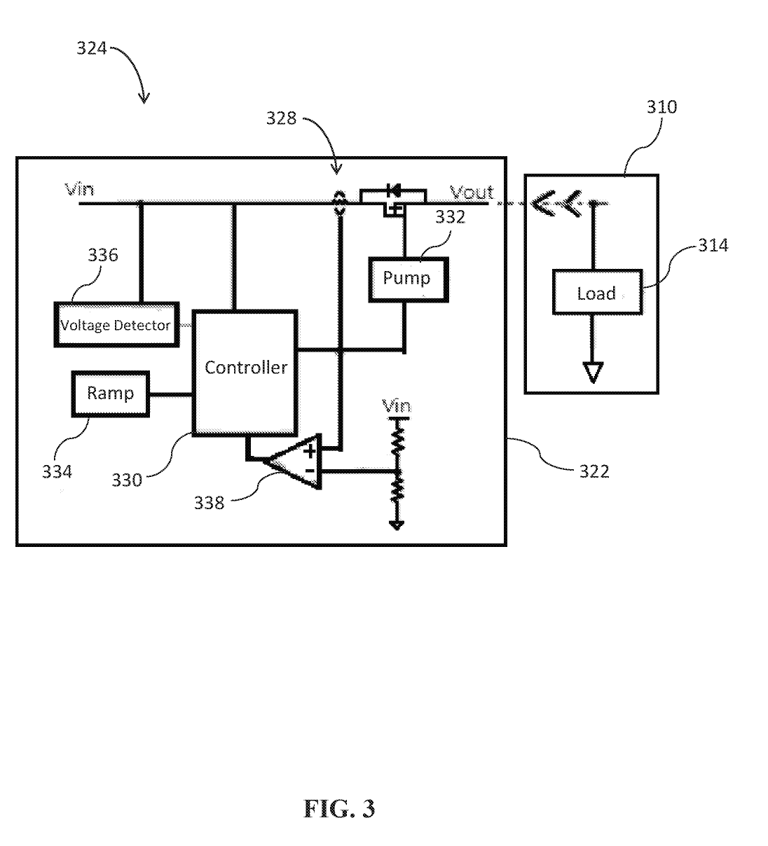

FIG. 3 illustrates an example of a control circuit 324 to control a voltage ramp rate in accordance with the disclosure. As described herein, the control circuit 324 may be included in a circuit board 322 of a heat source device (e.g., heat source device 120).

In various examples, a circuit board 322 may be coupled to a hot swappable fan module 310. The coupling may be a hot swapping such that the hot swappable fan module 310 may be coupled to and decoupled from the circuit board 322 while the heat source device is operating.

A load capacitance 314, which is located internal to the hot swappable fan module 310, may be in an uncharged state when the hot swappable fan module 310 is not coupled to the circuit board 322. When the hot swappable fan module 310 is coupled to the circuit board 322, the load capacitance 314 may be supplied of an amount of current at a rate determined by the control circuit 324.

As shown in FIG. 3, the control circuit 324 includes a gate controller 330 to control a voltage ramp rate of the control circuit 324 when the hot swappable fan module 310 is coupled to the circuit board 322. In various examples, the gate controller 330 may include a metal-oxide-semiconductor field-effect transistor (MOSFET), and may control the voltage ramp rate of the MOSFET such that an output voltage (e.g., Vout) of the control circuit 324 ramps at a particular rate. As such, when the hot swappable fan module 310 is coupled to the circuit board 322, the gate controller 330 may prevent a flow of an excessive amount of current that would have been, over a substantially short period of time, supplied in the absence of the gate controller 330.

In various examples, the control circuit 324 may include a charge pump 332 coupled to the gate controller 330. By utilizing the charge pump 332, the gate controller 330 can be capable of activating the MOSFET and maintaining the output voltage above a source voltage. Similarly, by utilizing the charge pump 332, the gate controller 330 can be capable of deactivating the MOSFET when necessary. In some examples, the MOSFET may be n-channel MOSFET, among other possibilities.

In some examples, the gate controller 330 is coupled to a passive ramp controller 334 such that the gate controller 330 controls the voltage ramp rate via the passive ramp controller 334. For example, the passive ramp controller 334 may determine a particular ramp rate at which the output voltage may ramp.

In various examples, the gate controller 330 may include a current sensor that detects a current change in the control circuit 324 when the hot swappable fan module 310 is coupled to the circuit board 322. For example, the gate controller 330, via the current sensor, may monitor a current flowing through a section 328, and may determine that the hot swappable fan module 310 is coupled to the circuit board 322 in response to a sudden increase of the current on the section 328.

In various examples, the gate controller 330 may further include a plurality of different components. For example, the gate controller 330 may include an op amp comparator to compare an output voltage to a reference voltage. For example, the gate controller 330 may include a logic circuit to perform a plurality of logic operations. For example, the gate controller 330 may include a gate driver to amplify the output voltage to a level that is comparable to the reference voltage.

In various examples, the control circuit 324 may include a voltage detector 336 that determines an input voltage (e.g., Vin) of the control circuit 324 and is coupled to the gate controller 330. In some examples, when the voltage detector 336 determines that the input voltage of the control circuit 324 is above a threshold, the voltage detector 336 may activate the gate controller 330 regardless of whether the hot swappable fan module 310 is coupled to the circuit board or not. As such, when the gate controller 330 is activated responsive to a determination that the input voltage is above the threshold, the output voltage of the control circuit 324 starts ramping.

In some examples, the control circuit 324 may reset an output voltage of the control circuit when the hot swappable fan module 310 is coupled to the circuit board. For example, the control circuit 324 may include a fast trip circuit 338 that resets the gate controller 330 when the hot swappable fan module 310 is coupled to the circuit board 322. In this event, the output voltage that has been ramping prior to coupling the hot swappable fan module 310 may be adjusted to a reset state such that, when the gate controller 330 is activated again, the output voltage may start ramping from a reset state. As such, an amount of current can be supplied to the hot swappable fan module 310 in a non-rushing manner.

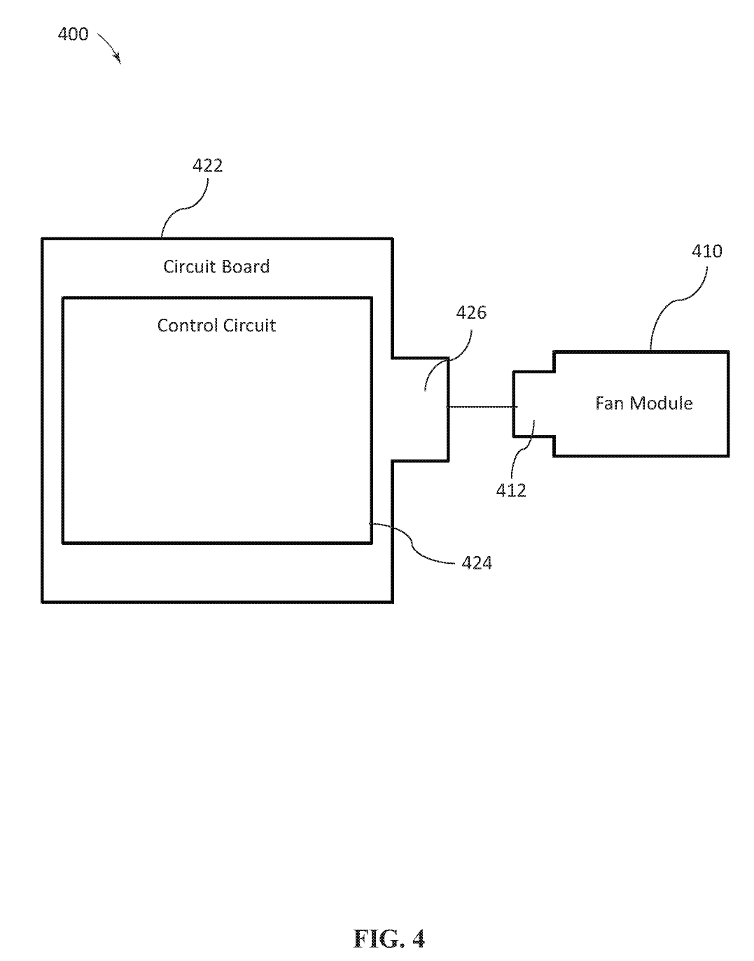

FIG. 4 illustrates an example of a system 400 to control a voltage ramp rate in accordance with the disclosure. As shown in FIG. 4, the system 400 may include a hot swappable fan module 410 and a circuit board 422. In various examples, the circuit board 422 may be a PCB, as described herein.

As shown in FIG. 4, the circuit board 422 may include a control circuit 424 and a protrusion 426. The protrusion 426 may be utilized to couple the circuit board 422 to the hot swappable fan module 410. For example, as shown in FIG. 4, the hot swappable fan module 410 may include a connector 412 that mates with the protrusion 426 of the circuit board 422.

The hot swappable fan module 410 may include a number of wires coupled to and extending from a fan blade device (not shown in FIG. 4). Each wire may be electrically coupled to a signal circuit that may be formed on the protrusion 426. As such, the number of wires may carry signals generated from the control circuit 424 to the hot swappable fan module 410. The connector 412 may collectively assemble the number of wires such that the number of wires, when the hot swappable fan module 410 being coupled to the circuit board 422, may be stably in contact with the signal circuit, for example, formed on the protrusion 426.

In various examples, the hot swappable fan module 410 may be in direct contact with the circuit board when the hot swappable fan module 410 is coupled to the circuit board 422. For example, the protrusion 426 may be an indistinguishable portion of the circuit board 422. As such, when connector 412 and the protrusion 426 mates each other, the hot swappable fan module 410 may receive a signal from the control circuit 424 via a signal circuit formed on the protrusion 426.

In various examples, the hot swappable fan module 410 may include a single connector (e.g., connector 412). Having a single connector to receive signals from the control circuit provides benefits such as increasing reliability.

In various examples, the control circuit 424 may reset an output voltage of the control circuit 424 when the hot swappable fan module 410 is coupled to the circuit board 422. For example, the output voltage, which has been ramping prior to coupling the hot swappable fan module 410 to the circuit board 422, may be adjusted to a reset state such that the output voltage starts ramping from the reset state when the hot swappable fan module 410 is coupled to the circuit board 422.

In various examples, the circuit board 422 may be located external to the hot swappable fan module 410 such that the heat source device (e.g., heat source device 120) may be capable of controlling the voltage ramp rate during the hot swapping. Stated differently, the hot swappable fan module 410 may not include a circuit board and a control circuit. As such, a mechanical/electrical design of the hot swappable fan module 410 can be simplified; and hence, reduce a cost of manufacturing, among other benefits.

In the foregoing detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense. As used herein, the designator “N”, particularly with respect to reference numerals in the drawings, indicates that a number of the particular feature so designated can be included with examples of the present disclosure. The designators can represent the same or different numbers of the particular features. Further, as used herein, “a number of” an element and/or feature can refer to one or more of such elements and/or features.

What is claimed:

1. A system, comprising:
a hot swappable fan module; and
a heat source device including a control circuit to control a voltage ramp rate of the control circuit when the hot swappable fan module is coupled to the heat source device.

2. The system of claim 1, wherein the hot swappable fan module is free of a signal-generating electronic.

3. The system of claim 1, wherein the hot swappable fan module only includes a connector and a fan blade device.

4. The system of claim 1, wherein the control circuit is to control the voltage ramp rate of the control circuit such that an output voltage of the control circuit ramps at a particular rate to activate the hot swappable fan module.

5. The system of claim 1, wherein the control circuit is to detect current changes when the hot swappable fan module is coupled to the heat source device.

6. The system of claim 1, wherein the heat source device includes a circuit board, on which the control circuit is implemented.

7. A printed circuit board (PCB), comprising:
a protrusion formed on an edge of the PCB, the protrusion to couple the PCB to a hot swappable fan module; and
a control circuit including a gate controller to control a voltage ramp rate of the control circuit when the hot swappable fan module is coupled to the PCB.

8. The PCB of claim 7, wherein the PCB includes a voltage detector that activates the gate controller when an input voltage of the control circuit is above a threshold.

9. The PCB of claim 7, wherein the gate controller is to control the voltage ramp rate via a passive ramp controller coupled to the gate controller.

10. The PCB of claim 7, wherein the gate controller is to control the voltage ramp rate of a metal-oxide-semiconductor field-effect transistor (MOSFET) such that an output voltage of the control circuit ramps at a particular rate to activate the hot swappable fan module.

11. The PCB of claim 7, wherein the control circuit includes a fast trip circuit that resets a gate controller to reset the output voltage of the control circuit when the hot swappable fan module is coupled to the circuit board.

12. The PCB of claim 7, wherein the control circuit further comprises a current sensor that detects a current change in the control circuit indicating that a load is applied when the hot swappable fan module is coupled to the heat source device.

13. The PCB of claim 7, wherein the control circuit is to reset the gate controller when the hot swappable fan module is coupled to the heat source device.

14. The PCB of claim 7, wherein the protrusion and the PCB comprise a single body.

15. The PCB of claim 7, wherein the protrusion is a signal connector.

16. A system, comprising:
a hot swappable fan module including a connector; and
a circuit board including a protrusion coupled to the connector and a control circuit to:
reset an output voltage of the control circuit when the hot swappable fan module is coupled to the protrusion via the connector; and
control a voltage ramp rate of the control circuit such that the output voltage starts ramping from a reset state, wherein the circuit board is included in a heat source device.

17. The system of claim 16, wherein the hot swappable fan module is in direct contact with the circuit board when the hot swappable fan module is coupled to the circuit board.

18. The system of claim 16, wherein the circuit board is located external to the hot swappable fan module.

19. The system of claim 16, wherein the circuit board is a printed circuit board (PCB).

20. The system of claim 16, wherein the hot swappable fan module includes a single connector.
